(19) United States
(12) Patent Application Publication
(10) Pub. No.: US 2015/0145611 A1
(43) Pub. Date: May 28, 2015

(54) OSCILLATOR CIRCUIT, OSCILLATOR, ELECTRONIC APPARATUS, AND MOVING OBJECT

(71) Applicant: Seiko Epson Corporation, Tokyo (JP)

(72) Inventors: Hisahiro ITO, Minowa (JP); Yasunari FURUYA, Fujimi (JP); Yoshiki MAKIUCHI, Minowa (JP); Hitoshi KOBAYASHI, Okaya (JP)

(21) Appl. No.: 14/553,079

(22) Filed: Nov. 25, 2014

(30) Foreign Application Priority Data
Nov. 27, 2013 (JP) 2013-245168

(51) Int. Cl. H03B 5/36

(52) U.S. Cl. CPC H03B 5/366; H03B 2200/004; H03B 2201/0208
USPC 331/116 R

(57) ABSTRACT

An oscillator circuit includes an oscillating amplifier circuit to which an oscillator element is connected, and which generates an oscillation signal, and a plurality of MOS type variable capacitance elements each having two terminals, one of which is electrically connected to the oscillating amplifier circuit, the MOS type variable capacitance elements have respective threshold voltages different from each other, a control voltage is applied to one of the terminals of each of the MOS type variable capacitance elements, and a reference voltage is applied to the other of the terminals of each of the MOS type variable capacitance elements. It is also possible for the MOS type variable capacitance elements to be different from each other in dope amount of impurities to a semiconductor layer below a gate electrode.

### BACKGROUND

1. Technical Field

The present invention relates to an oscillator circuit, an oscillator, an electronic apparatus, and a moving object.

2. Related Art

There has been known a method of applying a voltage to a variable capacitance element disposed inside an oscillator circuit to thereby vary the capacitance in order to make the oscillation frequency variable. The oscillator having the frequency controlled by a voltage is generally called a voltage controlled crystal oscillator (VCXO). In recent years, miniaturization is also required for crystal oscillators, and it has been progressing to making the oscillator circuit as an integrated circuit.

As the variable capacitance element used in the semiconductor integrated circuit, there has been known two types, namely a varactor diode and a MOS type variable capacitance element. The varactor diode has a variation ratio (a ratio between the minimum capacitance value and the maximum capacitance value) of the capacitance of roughly twofold in general, and it is unachievable to obtain a large frequency variation width. This results from the fact that a PN junction with a steep concentration gradient cannot be realized in the process for forming the integrated circuit.

In contract, the MOS type variable capacitance element can realize a larger variation width than in the varactor diode. The MOS type variable capacitance element takes a structure of connecting the source and the drain of a MOS transistor to each other, and the capacitance value steeply varies in the vicinity of a threshold voltage (Vₜ) of the MOS transistor. Therefore, it is hard to say that the relationship between a control voltage and an oscillation frequency is good in linearity compared to the varactor diode.

Therefore, in the disclosure of JP-A-2012-64915 (Document 1), by supplying a plurality of MOS type variable capacitance elements having the threshold of Vt with a common voltage and respective bias voltages different from each other, it is possible to make the relationship with the capacitance value approximate a linear relationship in a wider control voltage range.

However, in the disclosure of JP-A-2012-64915, it is necessary to apply the bias voltages different from each other to the respective MOS type variable capacitance elements, a circuit (a bias voltage supply section) for generating the bias voltages different from each other is required, and the circuit size is enlarged.

### SUMMARY

An advantage of some aspects of the invention is to provide an oscillator circuit, an oscillator, an electronic apparatus, a moving object, and so on with which the frequency variation width can be increased while ensuring the linearity of the frequency variation with respect to the control voltage variation, and at the same time, increase in circuit size can be suppressed.

The invention can be implemented as the following aspects or application examples.

### Application Example 1

An oscillator circuit according to this application example includes an oscillating amplifier circuit to which an oscillator element is connected, and which generates an oscillation signal, and a plurality of MOS type variable capacitance elements each having two terminals, one of which is electrically connected to the oscillating amplifier circuit, the MOS type variable capacitance elements have respective threshold voltages different from each other, a control voltage is applied to one of the terminals of each of the MOS type variable capacitance elements, and a reference voltage is applied to the other of the terminals of each of the MOS type variable capacitance elements.

The oscillator circuit according to this application example includes the MOS type variable capacitance elements having respective threshold voltages different from each other, and each having one terminal to which a control voltage is applied and the other terminal to which a reference voltage is applied. Therefore, it is possible to make the composite capacitance of the plurality of MOS type variable capacitance elements have linearity with respect to a control voltage variation, and as a result, it is possible to increase the frequency variation width while keeping the linearity of the frequency variation to the control voltage variation. On this occasion, it is not necessary to apply the bias voltages different from each other to the respective MOS type variable capacitance elements, and the circuit (the bias voltage supply section) for generating the bias voltages different from each other is not required, and therefore, it is also possible to avoid the increase in circuit size.

It should be noted that the MOS type variable capacitance element takes the structure of connecting the source and the drain of a MOS transistor to each other, and the capacitance value steeply varies in the vicinity of a threshold voltage of the MOS transistor. In other words, the threshold voltage of the MOS type variable capacitance element denotes a voltage at which the capacitance value changes steeply.

### Application Example 2

In the oscillator circuit according to the application example described above, the MOS type variable capacitance elements may be different from each other in dope amount of impurities to a semiconductor layer below a gate electrode.

According to the oscillator circuit related to this application example, the threshold voltage of the MOS type variable capacitance element is adjusted by changing the dope amount of the impurities to the semiconductor layer below the gate electrode. Since the same method as the manufacturing process of the existing MOS type transistor can be used, no dedicated manufacturing process is required, and it is possible to efficiently manufacture the oscillator circuit. It should be noted that the semiconductor layer below the gate electrode denotes, for example, a channel region, and the threshold voltage can be adjusted using the dope amount of the impurities such as arsenic, phosphorous, or boron.

### Application Example 3

In the oscillator circuit according to the application example described above, at least one of the MOS type variable capacitance elements may be an enhancement type, and at least one of the MOS type variable capacitance elements may be a depression type.

According to the oscillator circuit related to this application example, by combining the enhancement type MOS type variable capacitance element and the depression type MOS type variable capacitance element with each other, the linearity of the frequency variation to the control voltage variation can be improved. Here, the depression type MOS type variable capacitance element denotes the MOS type variable capacitance element having the threshold voltage no higher than 0V, and the enhancement type MOS type variable capacitance element denotes the MOS type variable capacitance element having the threshold voltage higher than 0V. By combining the enhancement type MOS type variable capacitance element and the depression type MOS type variable capacitance element with each other, and setting a voltage between the threshold voltage of the depression type MOS type variable capacitance element and the threshold voltage of the enhancement type MOS type variable capacitance element to the center voltage Vm in the variation characteristic of the composite capacitance to the control voltage variation, it is possible to linearly vary the composite capacitance by varying the control voltage based on the center voltage Vm, and thus, it is possible to realize the oscillator circuit which can easily be adjusted by the user.

### Application Example 4

In the oscillator circuit according to the application example described above, the control voltage may be commonly applied to the one of the terminals of all of the MOS type variable capacitance elements, and the reference voltage may be commonly applied to the other of the terminals of all of the MOS type variable capacitance elements.

### Application Example 5

In the oscillator circuit according to the application example described above, the control voltage may be commonly applied to the one of the terminals of all of the MOS type variable capacitance elements, and reference voltages different from each other may be applied to the other of the terminals of the respective MOS type variable capacitance elements.

According to the oscillator circuit related to this application example, it is possible to simplify the circuit configuration to reduce the circuit size by using at least one of the control voltage and the reference voltage in common. On this occasion, it is also possible to commonly apply the control voltage to the one of the terminals of all of the MOS type variable capacitance elements, and commonly apply the reference voltage to the other of the terminals of all of the MOS type variable capacitance elements. Further, it is also possible to commonly apply the control voltage to the one of the terminals of all of the MOS type variable capacitance elements, and apply reference voltages different from each other to the other of the terminals of the respective MOS type variable capacitance elements. In the latter case, the MOS type variable capacitance elements can also be adjusted not only by the threshold voltage, but also by the difference between the reference voltages to be applied.

### Application Example 6

An oscillator according to this application example includes the oscillator circuit according to any one of the application examples described above, and an oscillator element.

### Application Example 7

An electronic apparatus according to this application example includes the oscillator circuit according to any one of the application examples described above, or the oscillator according to the application example described above.

### Application Example 8

A moving object according to this application example includes the oscillator circuit according to any one of the application examples described above, or the oscillator according to the application example described above.

The oscillator, the electronic apparatus, and the moving object according to the application examples include the oscillator circuit described above including the MOS type variable capacitance elements having respective threshold voltages different from each other, and each having one end to which a control voltage is applied and the other end to which a reference voltage is applied. Therefore, according to the oscillator, the electronic apparatus, and the moving object related to the application examples, it is possible to increase the frequency variation width while keeping the linearity of the frequency variation with respect to the control voltage variation, and at the same time, suppress increase in circuit size.

### BRIEF DESCRIPTION OF THE DRAWINGS

The invention will now be described with reference to the accompanying drawings, wherein like numbers reference like elements.

FIG. 1 is a block diagram of a vibratory device including an oscillator circuit according to an embodiment of the invention.

FIG. 2 is a diagram showing a circuit configuration example of the oscillator circuit according to the embodiment.

FIG. 3 is a diagram for explaining the characteristics of an MOS type variable capacitance element.

FIG. 4 is a schematic cross-sectional view for explaining a configuration of the MOS type variable capacitance element.

FIG. 5 is a diagram for explaining linearity of a composite capacitance of the MOS type variable capacitance elements different in threshold voltage from each other.

FIG. 6 is a diagram for explaining the linearity of the composite capacitance in the case of increasing the number of the MOS type variable capacitance elements different in threshold voltage from each other.

FIG. 7 is a functional block diagram of an electronic apparatus.

FIG. 8 is a diagram showing an example of an appearance of the electronic apparatus.

FIG. 9 is a diagram showing an example of a moving object.

### DESCRIPTION OF AN EXEMPLARY EMBODIMENT

Hereinafter, a preferred embodiment of the invention will be described in detail with reference to the accompanying drawings. It should be noted that the embodiment described below does not unreasonably limit the contents of the invention as set forth in the appended claims. Further, all of the constituents described below are not necessarily essential elements of the invention.

### 1. Oscillator Circuit, Oscillator

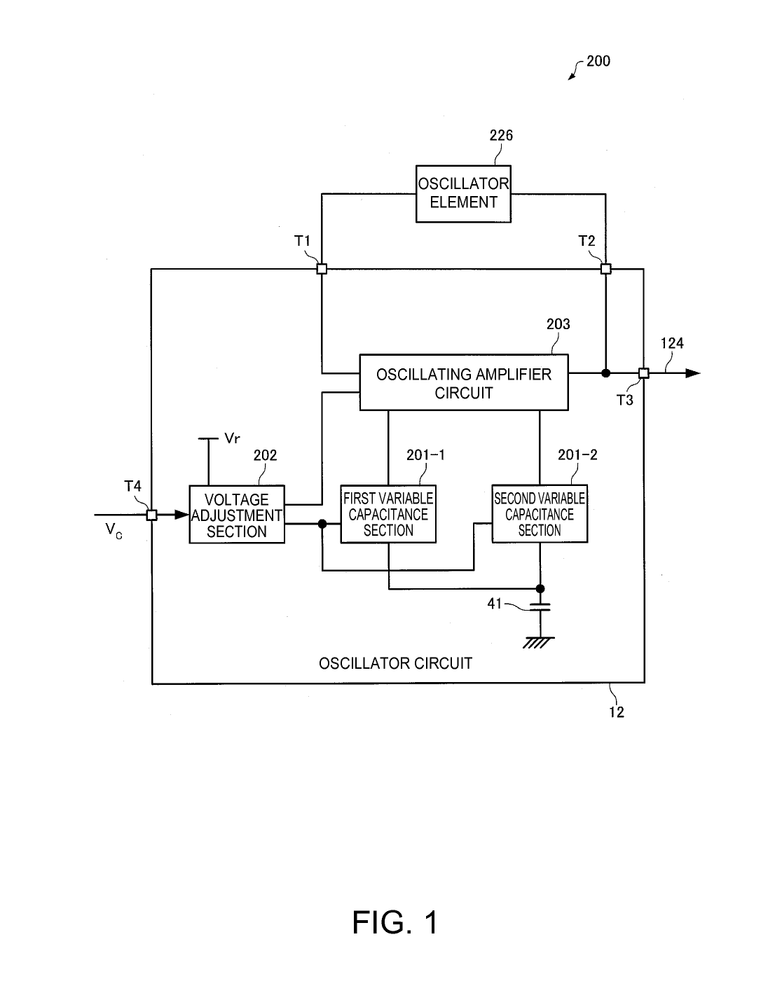

FIG. 1 is a block diagram of a vibratory device 200 including an oscillator circuit 12 according to the present embodiment. The oscillator circuit 12 includes an oscillating amplifier circuit 203 for oscillating an oscillator element 226 to generate an oscillation signal 124, a first variable capacitance section 201-1 and a second variable capacitance section 201-2 to be connected to the oscillating amplifier circuit 203, and a voltage adjustment section 202 for receiving a control voltage V_{C} and a reference voltage Vᵣ to perform a necessary adjustment, and supplying the oscillating amplifier circuit 203, the first variable capacitance section 201-1, and the second variable capacitance section 201-2 with the result. It should be noted that although in the present embodiment, the first variable capacitance section 201-1 and the second variable capacitance section 201-2 have the same configuration as described later, as another embodiment, one of the variable capacitance sections can be omitted, or a fixed capacitance section can be used instead of one of the variable capacitance sections. Further, as another embodiment, there can be adopted a configuration in which the voltage adjustment section 202 is not included.

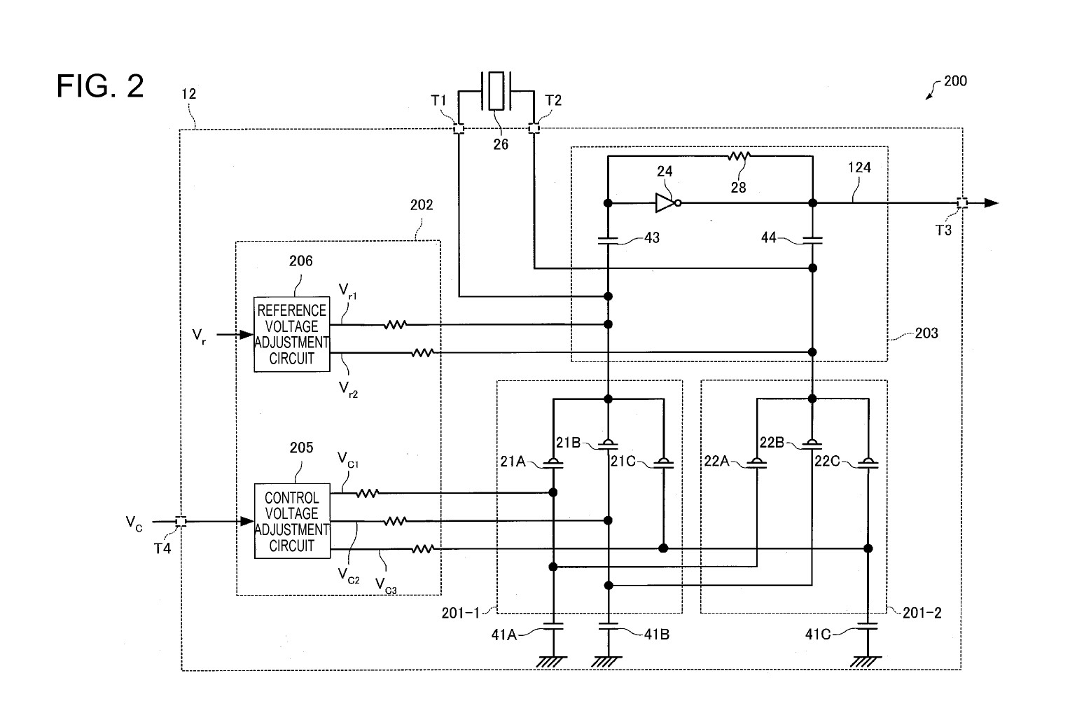

Here, as the oscillator element 226, there can be used, for example, an AT-cut crystal vibrator, an SC-cut crystal vibrator, a tuning-fork crystal vibrator, a surface acoustic wave (SAW) resonator, other piezoelectric vibrators, and a Micro Electro Mechanical Systems (MEMS) vibrator. In the present embodiment, the explanation will be presented assuming that an AT-cut crystal vibrator 26 is used as the oscillator element 226 (see FIG. 2).

The oscillator circuit 12 constitutes a part of the vibratory device 200. As the vibratory device 200, there can be cited, for example, an oscillator equipped with a vibrator as the oscillator element 226, and a physical quantity sensor equipped with a vibratory sensor element as the oscillator element 226. As the oscillator, there can be cited a piezoelectric oscillator (e.g., a crystal oscillator) such as a temperature compensated oscillator (e.g., TCXO), a voltage controlled oscillator (VCXO), or an oven-controlled oscillator (e.g., OCXO), an SAW oscillator, a silicon oscillator, an atomic oscillator, and so on. Further, as the physical quantity sensor, there can be cited an angular velocity sensor (a gyro sensor), an acceleration sensor, and so on. In the present embodiment, the explanation will be presented assuming that the oscillator circuit 12 constitutes a part of a voltage controlled crystal oscillator (VCXO) as a crystal oscillator capable of varying the oscillation frequency in accordance with the control voltage V_{C}. In other words, the vibratory device 200 shown in FIG. 1 corresponds to VCXO.

Further, the oscillator circuit 12 is made as an integrated circuit (IC) as shown in FIG. 1, and is provided with terminals T1, T2 to be connected to the oscillator element 226. Further, the oscillator circuit 12 includes a terminal T3 for outputting the oscillation signal 124, and a terminal T4 for receiving the control voltage V_{C}. It should be noted that in FIG. 1 and the following drawings, graphical description of a power supply voltage terminal and a ground terminal will be omitted. Further, it is possible for the oscillator circuit 12 to be integrated together with the oscillator element 226 to constitute the vibratory device 200 (VCXO) encapsulated in a package.

FIG. 2 is a diagram showing a circuit configuration example of the oscillator circuit 12 according to the present embodiment. The oscillating amplifier circuit 203 includes an inverter 24 equipped with a feedback resistor 28 and functioning as an analog inverting amplifier, and DC-cut capacitances 43, 44, wherein these constituents are connected as shown in FIG. 2. The inverter 24 is connected to the crystal vibrator 26 (corresponding to the oscillator element 226 shown in FIG. 1) in the input side and the output side via the terminals T1, T2, respectively, and oscillates the crystal vibrator 26 to generate the oscillation signal 124.

The first variable capacitance section 201-1 and the second variable capacitance section 201-2 are also connected to the crystal vibrator 26 in such a manner as shown in FIG. 2. The first variable capacitance section 201-1 includes MOS type variable capacitance elements 21A, 21B, and 21C, which are connected in parallel to each other. Further, the second variable capacitance section 201-2 includes MOS type variable capacitance elements 22A, 22B, and 22C, which are connected in parallel to each other. The first variable capacitance section 201-1 and the second variable capacitance section 201-2 have the same configuration, and the MOS type variable capacitance elements 21A, 21B, and 21C and the MOS type variable capacitance elements 22A, 22B, and 22C are the same, respectively, in characteristics.

In the first variable capacitance section 201-1, MOS type variable capacitance elements 21A, 21B, and 21C are different in threshold voltage from each other. Here, the threshold voltage denotes a voltage at which the capacitance value changes steeply. The first variable capacitance section 201-1 and the second variable capacitance section 201-2 have the same configuration, and the MOS type variable capacitance elements 22A, 22B, and 22C are also different in threshold voltage from each other. It should be noted that although in the present embodiment, the three MOS type variable capacitance elements 21A, 21B, and 21C are connected in parallel to each other in the first variable capacitance section 201-1, the number of the MOS type variable capacitance elements is not limited to three, but can be any number equal to or greater than two. On this occasion, the number of the MOS type variable capacitance elements in the second variable capacitance section 201-2 is also changed so as to be the same as in the first variable capacitance section 201-1.

A reference voltage Vᵣ₁ is applied to the gate terminals (the back gate terminals in the case of reversing the polarity) of the MOS type variable capacitance elements 21A, 21B, and 21C, and the control voltages V_{C1}, V_{C2}, and V_{C3} are applied respectively to the back gate terminals (the gate terminals in the case of reversing the polarity). The MOS type variable capacitance elements 21A, 21B, and 21C vary in capacitance in accordance with the difference between the reference voltage Vᵣ₁ and the control voltages V_{C1}, V_{C2}, and V_{C3}, respectively, and the frequency of the oscillation signal 124 also varies in accordance with the composite capacitance of these elements.

Further, a reference voltage Vᵣ₂ is applied to the gate terminals (the back gate terminals in the case of reversing the polarity) of the MOS type variable capacitance elements 22A, 22B, and 22C, and the control voltages V_{C1}, V_{C2}, and V_{C3} are applied respectively to the back gate terminals (the gate terminals in the case of reversing the polarity). The MOS type variable capacitance elements 22A, 22B, and 22C vary in capacitance in accordance with the difference between the reference voltage Vᵣ₂ and the control voltages V_{C1}, V_{C2}, and V_{C3}, respectively, and the frequency of the oscillation signal 124 also varies in accordance with the composite capacitance of these elements.

It should be noted that as shown in FIG. 2, the MOS type variable capacitance elements 21A, 22A are grounded via a fixed capacitance 41A, the MOS type variable capacitance elements 21B, 22B are grounded via a fixed capacitance 41B, and the MOS type variable capacitance elements 21C, 22C are grounded via a fixed capacitance 41C.

The voltage adjustment section 202 includes a control voltage adjustment circuit 205 and a reference voltage adjustment circuit 206. The control voltage adjustment circuit 205 adjusts the control voltage V_{C} received by the terminal T4 as necessary, and then outputs the result as the control voltages V_{C1}, V_{C2}, and V_{C3}. Further, the reference voltage adjustment circuit 206 adjusts the reference voltage V, generated from, for example, a power supply voltage V_{dd} (not shown) as necessary, and then outputs the result as the reference voltages Vᵣ₁, Vᵣ₂.

Here, the adjustments performed by the control voltage adjustment circuit 205 and the reference voltage adjustment circuit 206 are for adjusting, for example, a manufacturing variation caused in at least one of the MOS type variable capacitance elements 21A, 21B, 21C, 22A, 22B, and 22C. Therefore, there is no need for disposing a large circuit (a bias voltage supply section) for generating the bias voltages difference from each other for the respective MOS type variable capacitance elements 21A, 21B, 21C, 22A, 22B, and 22C as in the disclosure of JP-A-2012-64915. The control voltage adjustment circuit 205 and the reference voltage adjustment circuit 206 each can be realized using, for example, a resistive voltage dividing circuit for fine tuning small in circuit size, and so on.

Further, as another embodiment, at least one of the control voltage adjustment circuit 205 and the reference voltage adjustment circuit 206 can be eliminated. If the control voltage adjustment circuit 205 is eliminated, the control voltage V_{C} is directly output as the control voltages V_{C1}, V_{C2}, and V_{C3}. In other words, it is possible to apply the common control voltage V_{C} to the back gate terminals (the gate terminals in the case of reversing the polarity) of the MOS type variable capacitance elements 21A, 21B, 21C, 22A, 22B, and 22C. Further, if the reference voltage adjustment circuit 206 is eliminated, the reference voltage Vᵣ is directly output as the reference voltages Vᵣ₁, Vᵣ₂. In other words, it is possible to apply the common reference voltage Vᵣ to the gate terminals (the back gate terminals in the case of reversing the polarity) of the MOS type variable capacitance elements 21A, 21B, 21C, 22A, 22B, and 22C. It should be noted that the explanation will hereinafter be presented assuming that there is no need for adjusting the manufacturing variations of the MOS type variable capacitance elements 21A, 21B, 21C, 22A, 22B, and 22C, and the voltage adjustment section 202 outputs the reference voltage Vᵣ directly as the reference voltages Vᵣ₁, Vᵣ₂, and outputs the control voltage V_{C} directly as the control voltages V_{C1}, V_{C2}, and V_{C3}.

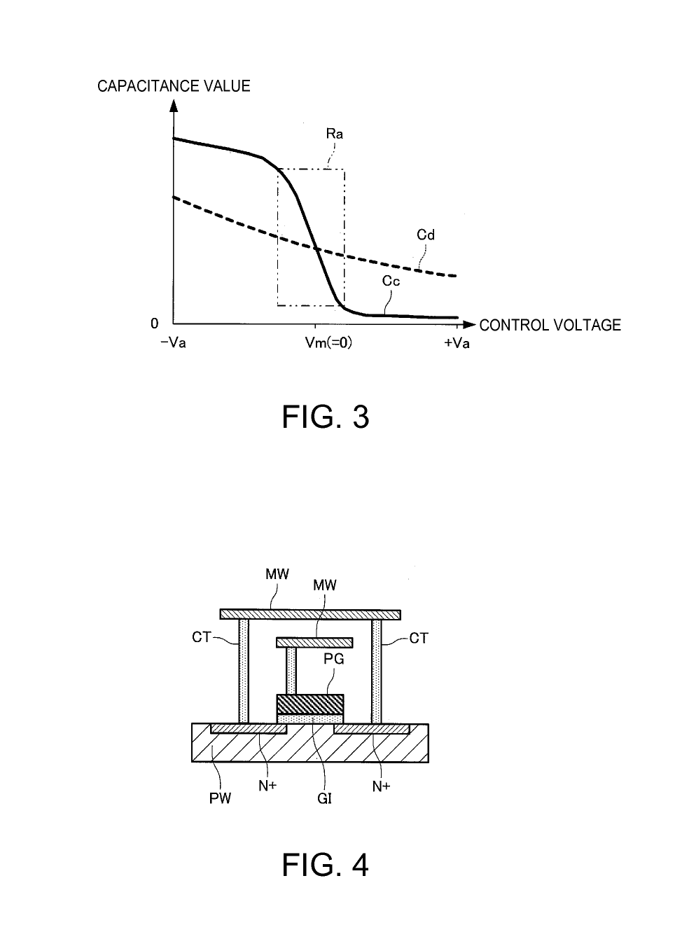

On this occasion, although inter-terminal voltages of the MOS type variable capacitance elements 21A, 21B, and 21C (or the MOS type variable capacitance elements 22A, 22B, and 22C) are equal to each other, since the threshold voltages thereof are different from each other, it is possible to increase the variation width of the composite capacitance of the first variable capacitance section 201-1 (the second variable capacitance section 201-2) with respect to the variation in the control voltage V_{C} to thereby increase the frequency variation width. Further, since it is not required to dispose the bias voltage supply section, the circuit size can also be reduced. This point will hereinafter be explained in detail with reference to FIGS. 3 through 6. It should be noted that since the first variable capacitance section 201-1 and the second variable capacitance section 201-2 have the same configuration, the first variable capacitance section 201-1 will hereinafter be explained alone, but the same applies to the second variable capacitance section 201-2.

FIG. 3 is a diagram for explaining the characteristics of one of the MOS type variable capacitance elements. In general, as the variable capacitance element used in the semiconductor integrated circuit, there has been known two types, namely a varactor diode and the MOS type variable capacitance element. The characteristic curve Cd indicated by a dotted line in FIG. 3 represents a C-V characteristic (the relationship between the capacitance value and the control voltage) of one varactor diode. Further, the characteristic curve Cc indicated by a solid line in FIG. 3 represents the C-V characteristic of one of the MOS type variable capacitance element. It is assumed that the control voltage is variable within a range of −Va through +Va centered on a center voltage Vm (here, the center voltage Vm=0V is assumed).

Here, in order to linearly adjust the oscillation frequency using the control voltage in the VCXO, it is necessary to use the variable capacitance element having the capacitance value roughly linearly varying in accordance with the variation in the control voltage. Further, the higher the variation ratio (the ratio between the minimum capacitance value and the maximum capacitance value) of the capacitance value is, the larger the variation width of the oscillation frequency becomes, and thus, the VCXO easy-to-use for the user can be realized. As represented by the characteristic curve Cd shown in FIG. 3, the capacitance value of the varactor diode varies roughly linearly with respect to the variation of the control voltage in the range of −Va through +Va, but the variation ratio of the capacitance value is low, and it is unachievable to obtain a large frequency variation width. In contrast, as represented by the characteristic curve Cc shown in FIG. 3, the capacitance value of the MOS type variable capacitance element steeply changes in the vicinity of the threshold voltage, and the variation ratio of the capacitance value is high. In the example shown in FIG. 3, the threshold voltage of the MOS type variable capacitance element is roughly equal to the center voltage Vm. However, the characteristic curve Cc only exhibits the linearity in a relatively limited range (the range Ra shown in FIG. 3) centered on the threshold voltage.

Therefore, in the disclosure of JP-A-2012-64915, the bias voltages different from each other are applied respectively to the MOS type variable capacitance elements connected in parallel to each other to thereby expand the range in which the composite capacitance exhibits the linearity. However, as described above, since it is necessary to dispose the bias voltage supply section, it results that the miniaturization of the VCXO is hindered. Further, there can also be cited a method of varying the C-V characteristic of the MOS type variable capacitance element using an extension coil to thereby expand the range in which the linearity is exhibited. However, if the extension coil is used as an essential component, the number of components increases, and therefore, it results that the miniaturization of the VCXO is hindered. Therefore, in the oscillator circuit 12 according to the present embodiment, the threshold voltages of the respective MOS type variable capacitance elements 21A, 21B, and 21C are made different from each other to thereby expand the range in which the linearity is exhibited.

FIG. 4 is a schematic cross-sectional view for explaining a configuration of the MOS type variable capacitance element. In FIG. 4, PW denotes a P-well, and N+ denotes drain and source regions of an N-type transistor. In the MOS type variable capacitance element shown in FIG. 4, the drain and the source are electrically connected to each other by contact electrodes CT and metal wiring MW, and the control voltage V_{C}, for example, is applied. Further, a polysilicon gate electrode PG is disposed on a gate oxide GI, and the reference voltage Vᵣ is applied.

The threshold voltage of the MOS type variable capacitance element can be adjusted by changing a dope amount of impurities to a semiconductor layer below the polysilicon gate electrode PG in the manufacturing process. The semiconductor layer below the gate electrode denotes, for example, a channel region. On this occasion, since the same method as in the manufacturing process of the existing MOS transistor can be used, it is possible to efficiently manufacture the oscillator circuit 12 including the MOS type variable capacitance elements. It should be noted that although the N-type MOS type variable capacitance element is shown in FIG. 4, it is also possible to use a P-type MOS type variable capacitance element.

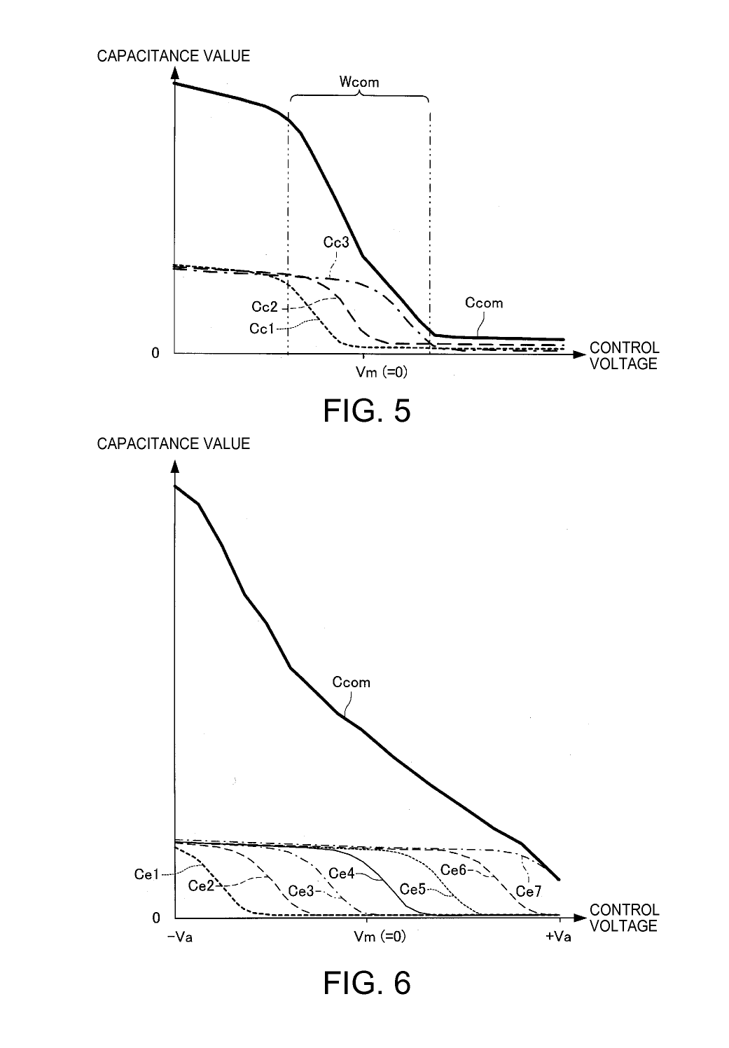

FIG. 5 is a diagram for explaining the linearity of the composite capacitance of the MOS type variable capacitance elements different in threshold voltage from each other. The characteristic curves Cc1, Cc2, and Cc3 indicated by the dotted lines shown in FIG. 5 each represent the C-V characteristic of one of the MOS type variable capacitance elements, and the characteristic curve Ccom indicated by the solid line represents the C-V characteristic of the composite capacitance of these elements. For example, it is possible to make the MOS type variable capacitance elements 21A, 21B, and 21C of the first variable capacitance section 201-1 correspond respectively to the characteristic curves Cc1, Cc2, and Cc3. In this case, the threshold voltages of the MOS type variable capacitance elements 21A, 21B, and 21C are adjusted by varying the dope amount of the impurities in the manufacturing process, and are different from each other. However, by connecting these elements in parallel to each other as shown in FIG. 2 (see the first variable capacitance section 201-1 shown in FIG. 2), the C-V characteristic of the composite capacitance becomes as represented by the characteristic curve Ccom. The characteristic curve Ccom exhibits the linearity in the range of Wcom shown in FIG. 5, which shows that the linearity range is expanded. Therefore, it is possible to increase the variation width of the composite capacitance with respect to the variation in the control voltage VC to thereby increase the frequency variation width.

Here, it is assumed that the MOS type variable capacitance element having the threshold voltage equal to or lower than 0V is a depression type MOS type variable capacitance element, and the MOS type variable capacitance element having the threshold voltage higher than 0V is an enhancement type MOS type variable capacitance element. In the example shown in FIG. 5, since the center voltage Vm is 0V, and the threshold voltages of the MOS type variable capacitance elements 21A, 21B (the characteristic curves Cc1, Cc2) are each equal to or lower than 0V, the MOS type variable capacitance elements 21A, 21B are categorized as the depression type. In contrast, the MOS type variable capacitance element 21C (the characteristic curve Cc3) has the threshold voltage higher than 0V, and is categorized as the enhancement type. As in the example shown in FIG. 5, by combining the enhancement type and the depression type, at least one of each of which is included therein, it is possible to arrange that the range, in which the linearity is exhibited, includes 0V in the variation characteristic of the composite capacitance. Therefore, by setting the voltage in the vicinity of 0V as the center voltage Vm, and varying the control voltage based on the center voltage Vm, it is possible to linearly vary the composite capacitance, and thus, the oscillator circuit 12 easy to adjust can be realized. Here, the center voltage Vm is equal to 0V in the example shown in FIG. 5, but can take a voltage between the threshold voltage of the depression type MOS type variable capacitance element and the threshold voltage of the enhancement type MOS type variable capacitance element. In other words, the center voltage Vm is not limited to 0V, but can be provided with a range. It should be noted that although the case in which all of the elements are the enhancement type or all of the elements are the depression type is excluded, a combination ratio between the enhancement type and the depression type is not particularly limited.

FIG. 6 is a diagram for explaining the linearity of the composite capacitance in the case of increasing the number of the MOS type variable capacitance elements different in threshold voltage from each other. Although in FIG. 2, there is shown the example of connecting the three MOS type variable capacitance elements 21A, 21B, and 21C in parallel to each other for the sake of convenience of graphical description, by connecting a larger number of MOS type variable capacitance elements in parallel to each other, the range in which the composite capacitance exhibits the linearity can significantly be expanded. FIG. 6 is a diagram based on the simulation result in the case in which, for example, seven MOS type variable capacitance elements are connected in parallel to each other. In this case, the C-V characteristics of the seven MOS type variable capacitance elements are as represented by the characteristic curves Ce1 through Ce7, respectively. Further, the C-V characteristic of the composite capacitance is as represented by the characteristic curve Ccom.

In the example shown in FIG. 6, the composite capacitance can be made to linearly vary in the entire variation range −Va through +Va of the control voltage centered on the center voltage Vm (=0V). If the C-V characteristic of the composite capacitance is realized only by applying the bias voltages different from each other to the respective MOS type variable capacitance elements, it is necessary for the bias voltage supply section to generate, for example, 0, V_{dd}/6, 2×V_{dd}/6, 3×V_{dd}/6, 4×V_{dd}/6, 5×V_{dd}/6, and V_{dd} (corresponding respectively to the characteristic curves Ce1, Ce2, Ce3, Ce4, Ce5, Ce6, and Ce7 shown in FIG. 6). In the case of connecting a large number of MOS type variable capacitance elements in parallel to each other in order to significantly expand the range in which the composite capacitance exhibits the linearity, it is necessary for the bias voltage supply section to accurately generate the number of intermediate voltages. Therefore, the circuit size inevitably increases.

In the oscillator circuit 12 according to the present embodiment, it is also possible to commonly use the voltage to be applied even in the case of connecting a number of MOS type variable capacitance elements in parallel to each other, and the bias voltage supply section is not required. Therefore, the circuit size can be reduced. As described hereinabove, the oscillator circuit 12 and the vibratory device 200 according to the present embodiment can increase the frequency variation width while keeping the linearity of the frequency variation with respect to the variation in the control voltage V_{C}, and at the same time, suppress increase in circuit size.

### 2. Electronic Apparatus

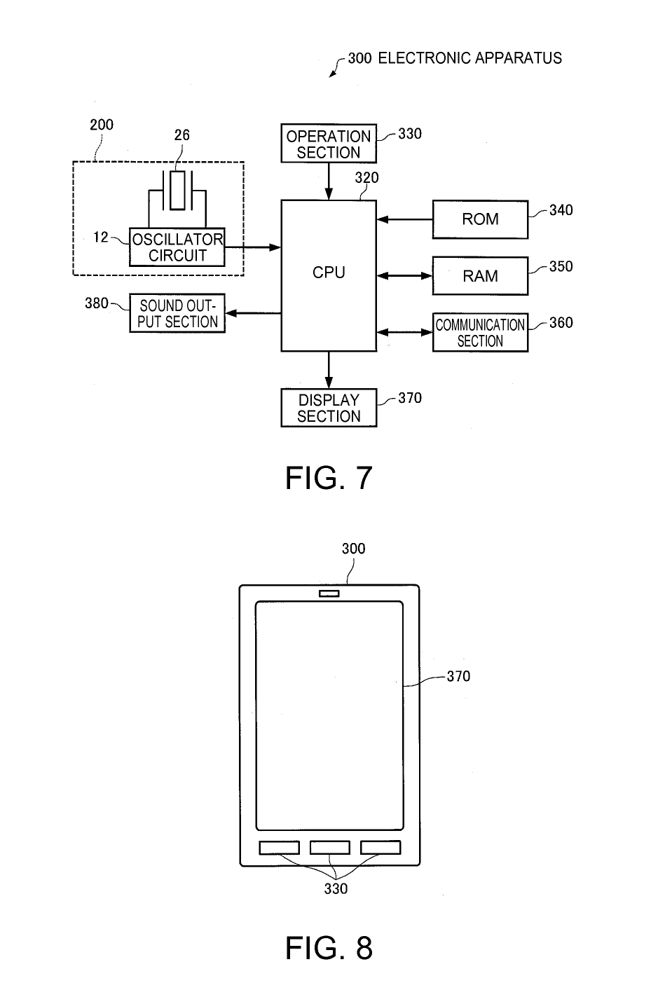

An electronic apparatus 300 according to the present embodiment will be explained with reference to FIGS. 7 and 8. It should be noted that the same elements as those shown in FIGS. 1 through 6 are denoted with the same reference numerals and symbols, and the explanation thereof will be omitted.

FIG. 7 is a functional block diagram of the electronic apparatus 300. The electronic apparatus 300 is configured including vibratory device 200 including the oscillator circuit 12 and the crystal vibrator 26, a central processing unit (CPU) 320, an operation section 330, a read only memory (ROM) 340, a random access memory (RAM) 350, a communication section 360, a display section 370, and a sound output section 380. It should be noted that the electronic apparatus 300 can also have a configuration obtained by eliminating or modifying some of the constituents (the sections) shown in FIG. 7, or adding another constituent to the configuration described above.

The vibratory device 200 supplies clock pulses (corresponding to the oscillation signal 124) not only to the CPU 320 but also to each of the sections (not shown). It should be noted that the vibratory device 200 can also be the oscillator having the oscillator circuit 12 and the crystal vibrator 26 integrated and encapsulated in a package.

The CPU 320 performs a variety of arithmetic processes and control processes using the clock pulses output by the oscillator circuit 12 in accordance with the program stored in the ROM 340 and so on. Specifically, the CPU 320 performs a variety of processes corresponding to the operation signal from the operation section 330, a process of controlling the communication section 360 for performing data communication with external devices, a process of transmitting a display signal for making the display section 370 display a variety of types of information, a process of making the sound output section 380 output a variety of sounds, and so on.

The operation section 330 is an input device including operation keys, button switches, and so on, and outputs the operation signal corresponding to the operation by the user to the CPU 320.

The ROM 340 stores a program, data, and so on for the CPU 320 to perform a variety of arithmetic processes and control processes.

The RAM 350 is used as a working area of the CPU 320, and temporarily stores, for example, the program and data retrieved from the ROM 340, the data input from the operation section 330, and the calculation result obtained by the CPU 320 performing operations in accordance with the various programs.

The communication section 360 performs a variety of control processes for achieving the data communication between the CPU 320 and the external devices.

The display section 370 is a display device formed of a liquid crystal display (LCD) or the like, and displays a variety of information based on the display signal input from the CPU 320.

Further, the sound output section 380 is a device, such as a speaker, for outputting sounds.

As described hereinabove, the oscillator circuit 12 included in the vibratory device 200 can increase the frequency variation width while keeping the linearity of the frequency variation with respect to the variation in the control voltage, and at the same time, suppress increase in circuit size. Therefore, the electronic apparatus 300 can obtain the clock pulse having a necessary frequency variation width from the oscillator circuit 12, and thus the miniaturization can be realized.

As the electronic apparatus 300, a variety of devices are possible. There can be cited, for example, a personal computer (e.g., a mobile type personal computer, a laptop personal computer, and a tablet personal computer), a mobile terminal such as a cellular phone, a digital still camera, an inkjet ejection device (e.g., an inkjet printer), a storage area network apparatus such as a router or a switch, a local area network apparatus, a mobile terminal base station apparatus, a television set, a video camera, a video recorder, a car navigation system, a pager, a personal digital assistance (including one having a communication function), an electronic dictionary, an electronic calculator, an electronic game machine, a gaming controller, a word processor, a workstation, a picture phone, a security television monitor, an electronic binoculars, a POS terminal, a medical instrument (e.g., an electronic thermometer, a blood pressure monitor, a blood glucose monitor, an electrocardiograph, ultrasonic diagnostic equipment, and an electronic endoscope), a fish finder, a variety of measuring instruments, gauges (e.g., gauges for cars, aircrafts, and boats and ships), a flight simulator, a head-mount display, a motion tracer, a motion tracker, a motion controller, and a pedestrian dead reckoning (PDR) system.

FIG. 8 is a diagram showing an example of an appearance of a smartphone as an example of the electronic apparatus 300. The smartphone as the electronic apparatus 300 is provided with buttons as the operation sections 330, and an LCD as the display section 370. Further, since the oscillator circuit 12 is included in the smartphone as the electronic apparatus 300, miniaturization of the smartphone can be realized.

### 3. Moving Object

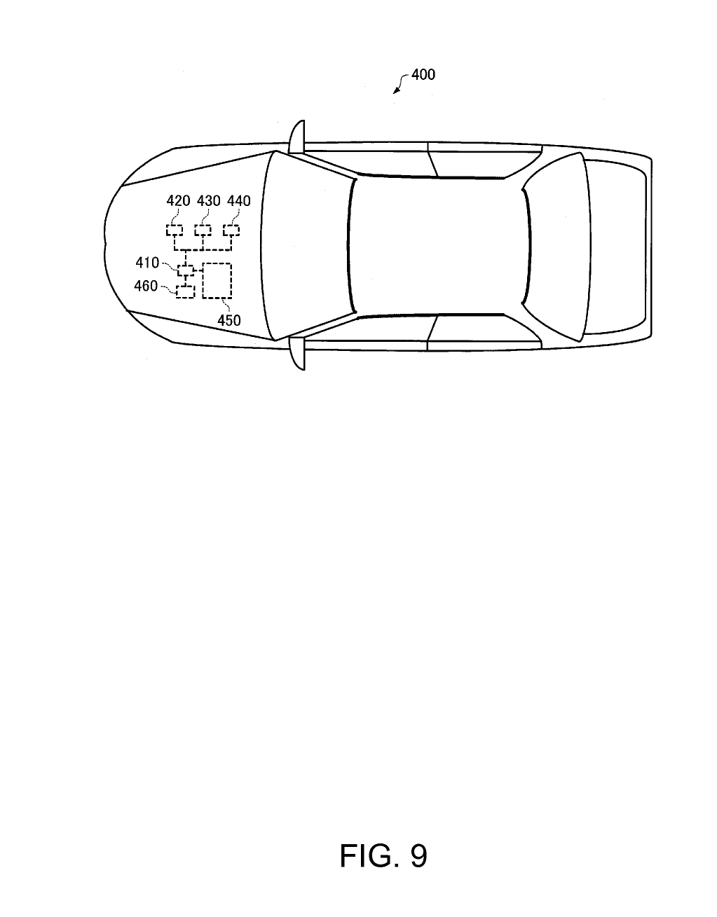

A moving object 400 according to the present embodiment will be explained with reference to FIG. 9. FIG. 9 is a diagram (a top view) showing an example of the moving object 400 according to the present embodiment. The moving object 400 shown in FIG. 9 is configured including an oscillator circuit 410, controllers 420, 430, and 440 for performing a variety of types of control of an engine system, a brake system, a keyless entry system, and so on, a battery 450, and a backup battery 460. It should be noted that the moving object 400 according to the present embodiment can have a configuration obtained by eliminating or modifying some of the constituents (sections) shown in FIG. 9, or adding another constituent thereto.

The oscillator circuit 410 corresponds to the oscillator circuit 12 described above, and is used after being connected to the oscillator element 226 not shown, but can also be replaced with the vibratory device 200 (the oscillator). Although the detailed explanation of other constituents will be omitted, high reliability is required in order to perform the control necessary for the movement of the moving object 400. For example, the backup battery 460 is provided in addition to the battery 450 to thereby enhance the reliability.

The clock pulses output by the oscillator circuit 410 are also required to have a predetermined oscillation frequency irrespective of the fluctuation in use environment. Since the oscillator circuit 410 includes the oscillator circuit 12, the variation width of the capacitance can be increased while keeping the linearity of the capacitance variation in the variable capacitance elements, and at the same time, suppress increase in circuit size. Therefore, it is possible for the moving object 400 to obtain the clock pulses (corresponding to the oscillation signal 124) having the frequency variation width capable of coping with a change in environment such as the temperature from the oscillator circuit 410. In other words, since the moving object 400 includes the oscillator circuit 12, the reliability can be ensured.

As such a moving object 400, a variety of types of devices are possible, and a vehicle (including an electric vehicle), an aircraft such a jet plane or a helicopter, a ship, a rocket, an artificial satellite, and so on can be cited.

### 4. Others

The invention includes configurations (e.g., configurations having the same function, the same way, and the same result, or configurations having the same object and the same advantage) substantially the same as the configuration explained in the above description of the embodiment. Further, the invention includes configurations obtained by replacing a non-essential part of the configuration explained in the above description of the embodiment. Further, the invention includes configurations providing the same functions and the same advantage, or configurations capable of achieving the same object, as the configuration explained in the description of the embodiment. Further, the invention includes configurations obtained by adding a known technology to the configuration explained in the description of the embodiment.

The entire disclosure of Japanese Patent Application No. 2013-245168, filed Nov. 27, 2013 is expressly incorporated by reference herein.

What is claimed is:

1. An oscillator circuit comprising:
an oscillating amplifier circuit to which an oscillator element is connected, and which generates an oscillation signal; and
a plurality of MOS type variable capacitance elements each having two terminals, one of which is electrically connected to the oscillating amplifier circuit,
wherein the MOS type variable capacitance elements have respective threshold voltages different from each other,
a control voltage is applied to one of the terminals of each of the MOS type variable capacitance elements, and
a reference voltage is applied to the other of the terminals of each of the MOS type variable capacitance elements.

2. The oscillator circuit according to claim 1, wherein
the MOS type variable capacitance elements are different from each other in dope amount of impurities to a semiconductor layer below a gate electrode.

3. The oscillator circuit according to claim 1, wherein
at least one of the MOS type variable capacitance elements is an enhancement type, and
at least one of the MOS type variable capacitance elements is a depression type.

4. The oscillator circuit according to claim 2, wherein
at least one of the MOS type variable capacitance elements is an enhancement type, and
at least one of the MOS type variable capacitance elements is a depression type.

5. The oscillator circuit according to claim 1, wherein
the control voltage is commonly applied to the one of the terminals of all of the MOS type variable capacitance elements, and
the reference voltage is commonly applied to the other of the terminals of all of the MOS type variable capacitance elements.

6. The oscillator circuit according to claim 2, wherein
the control voltage is commonly applied to the one of the terminals of all of the MOS type variable capacitance elements, and
the reference voltage is commonly applied to the other of the terminals of all of the MOS type variable capacitance elements.

7. The oscillator circuit according to claim 1, wherein
the control voltage is commonly applied to the one of the terminals of all of the MOS type variable capacitance elements, and
reference voltages different from each other are applied to the other of the terminals of the respective MOS type variable capacitance elements.

8. The oscillator circuit according to claim 2, wherein
the control voltage is commonly applied to the one of the terminals of all of the MOS type variable capacitance elements, and
reference voltages different from each other are applied to the other of the terminals of the respective MOS type variable capacitance elements.

9. An oscillator comprising:
the oscillator circuit according to claim 1; and
an oscillator element.

10. An oscillator comprising:
the oscillator circuit according to claim 2; and
an oscillator element.

11. An electronic apparatus comprising:
the oscillator circuit according to claim 1.

12. An electronic apparatus comprising:
the oscillator circuit according to claim 2.

13. An electronic apparatus comprising:
the oscillator according to claim 9.

14. An electronic apparatus comprising:
the oscillator according to claim 10.

15. A moving object comprising:
the oscillator circuit according to claim 1.

16. A moving object comprising:
the oscillator circuit according to claim 2.

17. A moving object comprising:
the oscillator according to claim 9.

18. A moving object comprising:
the oscillator according to claim 10.
